(19) United States
(12) Patent Application Publication
(10) Pub. No.: US 2007/0035364 A1
(43) Pub. Date: Feb. 15, 2007

(54) Titanium-tungsten alloy based mirrors and electrodes in bulk acoustic wave devices

(76) Inventors: Uppili Sridhar, Singapore (SG); Ralph N. Wall, Beaverton, OR (US); Guillaume Bouche, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/203,543

(22) Filed: Aug. 11, 2005

(51) Int. Cl. H03H 9/56

(52) U.S. Cl. 333/191

(57) ABSTRACT

Titanium-tungsten alloy based mirrors and electrodes in bulk acoustic wave devices simplify processing by eliminating the need for adhesion, barrier and seed layers, and preserve the advantages of tungsten layers. Alternate layers of high and low acoustic impedance materials are use, wherein the high acoustic impedance layers are titanium-tungsten alloy layers, preferably deposited by physical vapor deposition, and isotropically patterned with a wet etch. SiO₂ is preferably used for the low acoustic impedance layers, though other low acoustic impedance materials may be used if desired. Electrodes and loads may also be a Titanium-tungsten alloy. Titanium-tungsten alloys in the range of 3 to 15 percent of titanium by weight are preferred.

### BACKGROUND OF THE INVENTION

1. Field of the Invention

The present invention relates to the field of bulk acoustic wave devices.

2. Prior Art

The present invention pertains to piezoelectric resonators and filters whose primary application is for signal filtering and reference oscillators. These resonators are commonly referred to as FBAR (film bulk acoustic resonators) or BAW (bulk acoustic wave resonators). The term BAW encompasses also stacked resonators, fully coupled (Stack Crystal Filter or SCF) or partially coupled (Coupled Resonator Filters or CRF).

The resonator must be acoustically isolated from the mechanical substrate (typically a silicon wafer). This has been accomplished by an air gap (FBAR) or Bragg mirrors of alternating high and low acoustic impedance materials designed at one fourth the wavelength of interest (BAW). A high acoustic impedance material is also desirable for the electrodes. These devices are not new and are well documented in the literature. See for instance:
W. E. Newell, “Face-mounted piezoelectric resonators,” in proc. IEEE vol. 53, June 1965, pp. 575-581;
L. N. Dworsky and L. C. B. Mang, “Thin Film Resonator Having Stacked Acoustic Reflecting Impedance Matching Layers and Method,” U.S. Pat. No. 5,373,268, Dec. 13, 1994;
K. M. Lakin, G. R. Kline, R. S. Ketcham, and J. T. Martin, “Stacked Crystal Filters Implemented with Thin Films,” in 43rd Ann. Freq. Contr. Symp., May 1989, pp. 536-543;
R. Aigner, J. Ella, H.-J. Timme, L. Elbrecht, W. Nessler, S. Marksteiner, “Advancement of MEMS into RF-Filter Applications,” Proc. of IEDM 2002, San Francisco, Dec. 8-11, 2002, pp 897-900; and,
R. Aigner, J. Kaitila, J. Ella, L. Elbrecht, W. Nessler, M. Handtmann, T.-R. Herzog, W. Marksteiner, “Bulk-Acoustic-Wave Filters: Performance Optimization and Volume Manufacturing,” Proc. IEEE MTT-S International Microwave Symposium, vol. 3, 2003.

Tungsten is the common Bragg reflector material for the high acoustic impedance material. It is popular because of its high acoustic impedance. The primary deposition method for tungsten is by chemical vapor deposition (CVD). CVD tungsten deposition requires adhesion, barrier, and seed layers (e.g. titanium and titanium-nitride) that complicate the processing. Also CVD tungsten typically has a rough surface, limiting its use as an electrode material. CVD tungsten film stress can also be high. Tungsten can be deposited by PVD methods, but adhesion and particles are a significant challenge.

### BRIEF DESCRIPTION OF THE DRAWINGS

FIG. 1 is a cross-section of an exemplary embodiment of the present invention.

FIG. 2 is a cross section of a coupled resonator filter incorporating the present invention.

### DETAILED DESCRIPTION OF THE PREFERRED EMBODIMENTS

The present invention comprises the use of TiW as the high acoustic impedance material in the Bragg mirror stack and/or as the electrode composition or as a part of the electrode stack in the fabrication of FBAR or BAW devices (i.e. resonators and filters built from resonators). Classic IC fabrication methods are used for the basic manufacturing sequences, including depositions, photolithography, and etch processes. MEMS techniques may also be employed for packaging and resonator acoustic isolation from the substrate. The low acoustic impedance material may be silicon dioxide (SiO₂) though other low acoustic impedance layers could be used if desired, such as a carbon based dielectric or Silicon-based polymer, or polysilicon, or other low-loss polymers such as polyimide, among other materials. TiW refers to a binary alloy of titanium and tungsten. Typically the titanium content should not exceed 15 percent by weight. Equally effective results have been obtained with 3 percent and 10 percent titanium by weight. The TiW is deposited by physical vapor deposition (PVD) in any commercially available sputter deposition system. PVD TiW is a low cost material and has high acoustic impedance, excellent adhesion to oxide layers, tunable film stress, and relatively smooth surfaces. Resist adhesion to TiW is good, allowing long wet etch patterning. Because TiW is easily patterned by isotropic wet etch methods, a planarized architecture is not needed. Thus, TiW is found to be a good BAW Bragg mirror layer or electrode material having superior characteristics in comparison to the substantially pure tungsten (W) used in the prior art.

Thus the preferred embodiments of the invention consist of utilizing PVD TiW material as the high acoustic impedance Bragg reflector layers, electrode layers, and/or shunt loads on parallel resonators for FBAR or BAW. Compared to CVD tungsten, TiW eliminates the need for seed and adhesion layers, it results in a smooth film, and the film stress is easily tailored by common PVD process parameters (e.g. temperature, pressure, bias, etc.). Acoustic velocity of TiW is not significantly compromised, particularly when compared to the full CVD tungsten stack including adhesion and seed layers. AIN (aluminum nitride) piezoelectric quality when grown on TiW can be good. TiW is more easily patterned than CVD tungsten because there are no adhesion, barrier, or seed layers to remove. For example, Ti/TiN patterning typically requires anisotropic plasma etching and hence requires full planarization of the device. A fully planarized architecture is more complex and is less likely to produce acceptable device uniformity (i.e. die yield will suffer).

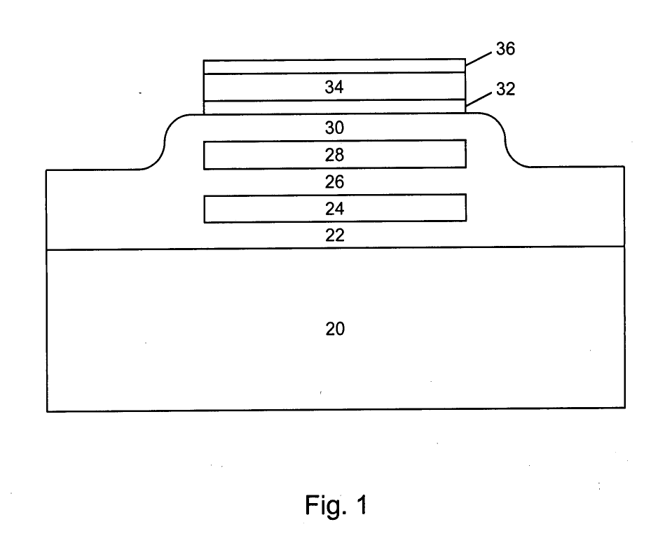

Typical structures incorporating the present invention may be the same as or similar to structures using tungsten as the high acoustic impedance layers in such devices, though the relative ease in processing with the present invention avoids some of the difficulties and necessary extra processing steps to achieve the desired result with tungsten alone. By way of example, a cross section of an exemplary structure may be seen in FIG. 1. This exemplary structure is fabricated on a silicon substrate 20 having a grown or deposited oxide (SiO₂) layer 22 thereon. Then a TiW layer is put down by physical vapor deposition (PVD) and patterned using a conventional photo-resist and wet etch process to form a high acoustic impedance layer 24. Note that no adhesion, barrier, or seed layer is required or used. Then another SiO₂ layer 26 is deposited as a low acoustic impedance layer, followed by the depositing and patterning of another layer of TiW to form a second high acoustic impedance layer 28. Because TiW is easily patterned by isotropic wet etch methods, a planarized architecture is not needed. In that regard, the patterned layer of TiW 24 will “print” through the oxide layer 26, creating a nonplanarized surface duplicating the pattern, so that the subsequent TiW layer, an isotropic layer, will coat the sides of the pattern, requiring additional etching time to completely remove the side regions of the second TiW layer. However the absence of adhesion, barrier and/or seed layers coupled with the ease of wet etching TiW makes this process relatively easy without planarization. This is followed by the deposition of another low acoustic impedance SiO₂ layer 30 over which, an electrode layer 32 is deposited and patterned, then a piezoelectric layer 34 is deposited and another electrode layer 36 is deposited and patterned. Preferably, but not necessarily, the electrode layers are TiW layers also. Layers 24, 26, 28 and 30 are layers that are typically optimized in thickness for the application. In many, but not all applications, this will be one quarter of a wavelength thick at a frequency of interest, as is preferably layer 22, as it is part of the reflector stack. Note that in this embodiment, two TiW layers are used, though a different number may be used for the stack of alternate layers of high and low acoustic impedance material on the substrate, such as as few as one TiW alloy layer, and as many as four TiW layers or more may be used. Note also that the oxide layers need not be patterned, as they do not affect the performance of any other BAW on the same substrate. In the preferred embodiment, the piezoelectric layer is AIN (aluminum nitride), though other piezoelectric layers could be used if desired. Similarly, while SiO₂ is preferably used, other low acoustic impedance layers could be used if desired, such as a carbon based dielectric or silicon-based polymer, or polysilicon, or other low-loss polymers such as polyimide.

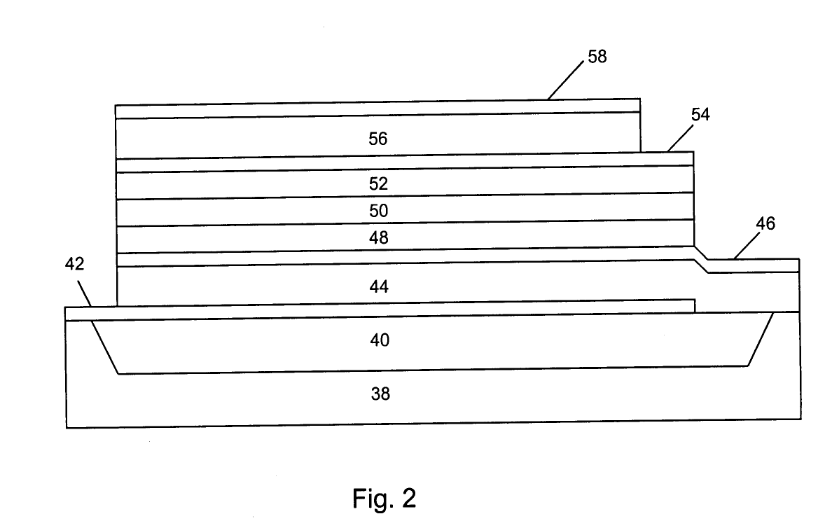

Now referring to FIG. 2, another embodiment of the present invention may be seen. This embodiment shows a decoupled, stacked bulk acoustic resonator, specifically a second resonator stacked over a first resonator, referred to as a coupled resonator filter. As shown in the Figure, the first resonator comprises piezoelectric layer 44 and electrode layers 42 and 46 supported over cavity 40 in substrate 38 to provide isolation between the first resonator and the substrate. In this particular embodiment, above electrode 46 is a stack of alternate layers of low acoustic impedance materials and high acoustic impedance material supporting a further resonator comprising piezoelectric layer 56 sandwiched between electrode layers 54 and 58. In the specific embodiment shown, the stack comprises a layer of low acoustic impedance material 48, a layer of high acoustic impedance material 50 and a further layer of low acoustic impedance material 52. In the embodiment shown, the layer of high acoustic impedance material 50 and/or electrodes 54 and 58 and/or electrodes 42 and 46 may comprise a titanium tungsten alloy in accordance with the present invention. In the limit, the stack of layers 48, 50 and 52 may comprise a single layer of titanium tungsten alloy, or may comprise a stack of alternate layers, including more than a single titanium tungsten alloy layer, in any case referred to herein collectively as a coupling layer. The selection of the number of layers and the acoustic thickness of the layers in the coupling layer may provide isolation or controlled coupling between the resonators, as desired.

In a typical device incorporating the present invention, the electrode layers and the piezoelectric layers will be patterned to form more than one resonant device, though for convenience, such multiple resonant devices are simply referred to herein and in the appended claims as a resonator or resonators.

Thus the present invention solves the inherent process related problems of CVD tungsten, namely a rough surface, high stress, and poor adhesion. In that regard, by using stress-tunable processed titanium-tungsten PVD films, controlling the deposition temperature, pressure and deposition rate, the stress in the titanium-tungsten PVD films may be set as desired. At the same time, the excellent acoustic properties of tungsten are fully maintained. The benefit of PVD TiW is that it presents a smooth surface, the stress can be tuned to optimize the overall integration scheme, and adhesion/seed layers are not needed. Thus, TiW offers a lower cost process with equal or better performance and with increased process integration latitude.

While certain preferred embodiments of the present invention have been disclosed and described herein for purposes of illustration and not for purposes of limitation, it will be understood by those skilled in the art that various changes in form and detail may be made therein without departing from the spirit and scope of the invention.

What is claimed is:

1. A piezoelectric resonator comprising:
a substrate;
a stack of alternate layers of high and low acoustic impedance material on the substrate;
a piezoelectric layer, including electrode contacts to first and second sides of the piezoelectric layer, on the stack;
the high acoustic impedance material being a titanium-tungsten alloy.

2. The resonator of claim 1 wherein the titanium-tungsten layer is deposited by physical vapor deposition.

3. The resonator of claim 1 wherein the titanium-tungsten alloy is less than 15% titanium by weight.

4. The resonator of claim 3 wherein the titanium-tungsten alloy is at least 3% titanium by weight.

5. The resonator of claim 1 wherein the layers of low and high acoustic impedance material in the stack of alternating high and low acoustic material are in direct contact without intervening layers therebetween.

6. The resonator of claim 1 wherein the electrode contacts comprise a titanium-tungsten alloy.

7. The resonator of claim 1 further comprising a parallel resonator having a shunt load, the shunt load also comprising a titanium-tungsten alloy.

8. The resonator of claim 1 wherein the stack includes two layers of titanium-tungsten.

9. The resonator of claim 1 wherein the low acoustic impedance material is SiO₂.

10. The resonator of claim 1 wherein the low acoustic impedance material is a carbon based dielectric.

11. The resonator of claim 1 wherein the low acoustic impedance material is a low loss polymer.

12. The resonator of claim 1 where the low acoustic impedance material is selected from the group consisting of a silicon-based polymer, polysilicon and a polyimide.

13. The resonator of claim 1 wherein the substrate is a silicon substrate.

14. The resonator of claim 1 wherein the titanium-tungsten layers are deposited layers using stress-tunable processed titanium-tungsten PVD films.

15. A piezoelectric resonator comprising:
a silicon substrate;
a stack of alternate layers of high and low acoustic impedance material on the substrate, each layer being optimized for the application;
a piezoelectric layer, including electrode contacts to first and second sides of the piezoelectric layer, on the stack;
the high acoustic impedance material being a PVD deposited titanium-tungsten alloy.

16. The resonator of claim 15 wherein the titanium-tungsten alloy is less than 15% titanium by weight.

17. The resonator of claim 16 wherein the titanium-tungsten alloy is at least 3% titanium by weight.

18. The resonator of claim 15 wherein the layers of low and high acoustic impedance material in the stack of alternating high and low acoustic material are in direct contact without intervening layers therebetween.

19. The resonator of claim 15 wherein the electrode contacts are also a titanium-tungsten alloy fully or in part.

20. The resonator of claim 15 further comprising a parallel resonator having a shunt load, the shunt load also being a titanium-tungsten alloy.

21. The resonator of claim 15 wherein the stack includes two layers of titanium-tungsten.

22. The resonator of claim 15 wherein the low acoustic impedance material is SiO₂.

23. The resonator of claim 15 wherein the low acoustic impedance material is a carbon based dielectric.

24. The resonator of claim 15 wherein the low acoustic impedance material is silicon nitride.

25. The resonator of claim 15 wherein the titanium-tungsten is a deposited layer using stress-tunable processed titanium-tungsten PVD films.

26. A method of fabrication of piezoelectric resonators comprising:
a) providing a low acoustic impedance layer;
b) depositing a titanium-tungsten alloy layer by physical vapor deposition directly on the low acoustic impedance layer;
c) patterning the titanium-tungsten alloy layer;
d) depositing a low acoustic impedance layer directly on the titanium-tungsten alloy layer;
e) repeating b), c) and d) at least once;
f) depositing a first electrode layer;
g) depositing a piezoelectric layer; and,
h) depositing a second electrode layer;
the low acoustic impedance layers and the titanium-tungsten alloy layers being optimized for the application.

27. The method of claim 26 wherein the first electrode layer is first deposited and patterned, the piezoelectric layer is deposited and the second electrode layer is then deposited and patterned.

28. The method of claim 26 wherein the electrode layers comprise titanium-tungsten alloy layers deposited by physical vapor deposition.

29. The method of claim 26 wherein the low acoustic impedance layers are SiO₂ layers.

30. The method of claim 26 wherein the titanium-tungsten alloy is less than 15% titanium by weight.

31. The method of claim 30 wherein the titanium-tungsten alloy is at least 3% titanium by weight.

32. The method of claim 26 further comprising a parallel resonator having a shunt load, the shunt load also being a titanium-tungsten alloy.

33. The method of claim 26 wherein the low acoustic impedance material is a carbon based dielectric.

34. The method of claim 26 wherein the low acoustic impedance material is a low loss polymer.

35. The method of claim 26 wherein the low loss acoustic impedance material is selected from the group consisting of a silicon-based polymer, polysilicon and a polyimide.

36. The method of claim 26 wherein in a), the low acoustic impedance layer is formed on a silicon substrate.

37. In a coupled resonator filter, a coupling layer between staked resonators comprising at least one titanium-tungsten alloy layer.
